(19) United States
(12) Patent Application Publication
(10) Pub. No.: US 2008/0295763 A1
(43) Pub. Date: Dec. 4, 2008

(54) Apparatus for manufacturing Group III nitride semiconductor and method for manufacturing Group III nitride semiconductor

(75) Inventors: Koji Hirata, Aichi-ken (JP); Shiro Yamazaki, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 12/155,108

(22) Filed: May 29, 2008

(30) Foreign Application Priority Data
May 30, 2007 (JP) 2007-144220

(51) Int. Cl. C30B 7/08

(52) U.S. Cl. 117/70; 117/206

(57) ABSTRACT

A Group III nitride semiconductor crystal is grown according to a flux method. After completion of the crystal-growing process, Na is discharged from a crucible by a recovery device when the temperature of the crucible is 100° C. or higher, and is held in a holding vessel in a liquid state. The recovered Na can be drawn from the holding vessel via a faucet. Na remaining after completion of the crystal-growing process does not contain impurities of high vapor pressure, and is thus of high purity. Therefore, reuse, as flux, of the recovered Na enables manufacture of a Group III nitride semiconductor whose concentration of impurities is low.

### BACKGROUND OF THE INVENTION

1. Field of the Invention

The present invention relates to a method for manufacturing a Group III nitride semiconductor according to a flux method and to an apparatus for manufacturing a Group III nitride semiconductor according to a flux method.

2. Description of the Related Art

Conventionally, an Na flux method for growing a Group III nitride semiconductor crystal is known. According to the Na flux method, sodium (Na) and gallium (Ga) are melted, and a resultant mixed melt is maintained at a temperature of about 800° C. and is subjected to reaction with nitrogen under a high pressure of about 100 atmospheres, thereby growing a gallium nitride (GaN) crystal on the surface of a seed crystal.

Japanese Patent Application Laid-Open (kokai) No. 2006-131454 discloses a method for manufacturing a Group III nitride semiconductor according to an Na flux method. According to the manufacturing method, after completion of a crystal-growing process, the mixed melt is allowed to cool to room temperature, and is treated with ethanol so as to remove Na, thereby yielding a GaN crystal.

In the above-mentioned treatment with ethanol, reaction with ethanol yields sodium hydroxide (NaOH). However, since yielding Na from NaOH is not easy, Na remaining after the crystal-growing process has been disposed of without being reused.

### SUMMARY OF THE INVENTION

In view of the foregoing, an object of the present invention is to provide an apparatus for manufacturing a Group III nitride semiconductor according to an Na flux method which enables reuse of Na, as well as a method for manufacturing a Group III nitride semiconductor according to an Na flux method which enables reuse of Na.

In order to solve the aforementioned problems, the following means are effective.

As a first means, the present invention provides an apparatus for manufacturing a Group III nitride semiconductor comprising a reaction vessel which holds, in a molten state, a Group III metal, and flux containing at least an alkali metal; a first heating device for heating the reaction vessel; and a supply device for supplying a gas containing at least nitrogen into the reaction vessel. The apparatus further comprises discharge piping extending into the reaction vessel, and a recovery device connected to the discharge piping and adapted to discharge, after completion of crystal growth, the flux liquefied in the reaction vessel.

Sodium (Na) or potassium (K) can be used as the flux. The flux may contain, for example, an alkaline-earth metal, such as calcium (Ca), or lithium (Li).

As discharging means in the recovery device, there can be used a pump that can establish a reduced pressure or pressurization, such as a vacuum pump, rotor pump or a cylinder pump. Discharging may be sucking by a reduced pressure or transporting by pressurization. By means of a pump or the like, the recovered flux can be returned under pressure to the reaction vessel from the recovery device through the discharge piping.

As a second means, the present invention provides an apparatus for manufacturing a Group III nitride semiconductor according to the first means, further comprising a second heating device for heating the discharge piping.

As a third means, the present invention provides an apparatus for manufacturing a Group III nitride semiconductor according to the first or second means, wherein the flux contains Na.

As a fourth means, the present invention provides an apparatus for manufacturing a Group III nitride semiconductor according to any one of the first to third means, wherein the recovery device comprises a holding vessel for holding the flux in a liquid state.

As a fifth means, the present invention provides an apparatus for manufacturing a Group III nitride semiconductor according to the fourth means, wherein the holding vessel has a faucet through which the flux is drawn from the holding vessel, and the faucet is disposed within a glove box filled with a gas which does not react with the flux.

The glove box is filled with an inert gas, such as argon gas.

As a sixth means, the present invention provides an apparatus for manufacturing a Group III nitride semiconductor according to any one of the first to fifth means, wherein the recovery device comprises a vacuum pump, and the flux is discharged by means of the vacuum pump.

As a seventh means, the present invention provides an apparatus for manufacturing a Group III nitride semiconductor according to any one of the first to fifth means, wherein the recovery device comprises a cylinder pump, and the flux is discharged by means of the cylinder pump.

As an eighth means, the present invention provides an apparatus for manufacturing a Group III nitride semiconductor according to any one of the first to seventh means, wherein the Group III metal is gallium.

As a ninth means, the present invention provides a method for manufacturing a Group III nitride semiconductor according to a flux method in which a Group III nitride semiconductor crystal is grown from a mixed melt of a Group III metal and flux containing at least an alkali metal, and a gas containing at least nitrogen. The method comprises a recovery step of, after completion of crystal growth, discharging the flux at a temperature higher than a melting point of the flux for recovery of the flux.

As a tenth means, the present invention provides a method for manufacturing a Group III nitride semiconductor according to the ninth means, wherein the flux contains Na.

As an eleventh means, the present invention provides a method for manufacturing a Group III nitride semiconductor according to the tenth means, wherein the recovery step is carried out when the temperature of the flux is within a range of 100° C. to 200° C. inclusive.

The temperature of the flux is desirably 200° C. or lower in view of easy recovery of the flux, and is desirably 100° C. or higher, since the melting point of Na is about 98° C.

According to the apparatus for manufacturing a Group III nitride semiconductor of the first means, flux that remains after completion of crystal growth can be recovered through the discharge piping by means of the recovery device, and the recovered flux can be reused. The recovered flux does not contain impurities of high vapor pressure. Therefore, reuse of the recovered flux can yield a Group III nitride semiconductor of high quality whose concentration of impurities is low.

According to the second means, the heating device heats the discharge piping so as to maintain the discharge piping at a temperature equal to or higher than the melting point of flux. This prevents solidification of flux in the discharge piping, which could otherwise cause clogging of the discharge piping with solidified flux.

According to the third means, Na can be used as flux.

According to the fourth means, the holding vessel holds the flux in a liquid state. This facilitates reuse of the flux and enhances work efficiency.

According to the fifth means, the holding vessel has the faucet, and the faucet is disposed within the glove box. Thus, the flux can be drawn from the holding vessel through the faucet without involvement of oxidation of the flux or a like problem. This enhances convenience and work efficiency.

According to the sixth and seventh means, the vacuum pump and the cylinder pump can be used to discharge the flux.

According to the eighth means, gallium can be used as the Group III metal. Thus, the apparatus for manufacturing a Group III nitride semiconductor of the present invention can manufacture gallium nitride (GaN).

The method for manufacturing a Group III nitride semiconductor according to any one of the ninth to eleventh means can recover and reuse the flux.

The present invention can be applied to manufacture of a Group III nitride semiconductor according to an Na flux method.

### BRIEF DESCRIPTION OF THE DRAWING

FIG. 1 is a schematic diagram showing the configuration of a Group-III-nitride-semiconductor manufacturing apparatus according to Embodiment 1 of the present invention;

FIG. 2 is a schematic diagram showing the configuration of a Group-III-nitride-semiconductor manufacturing apparatus according to Embodiment 2 of the present invention; and

FIG. 3 is a schematic diagram showing the configuration of a Group-III-nitride-semiconductor manufacturing apparatus according to Embodiment 3 of the present invention.

### DESCRIPTION OF THE PREFERRED EMBODIMENTS

Embodiments of the present invention will next be described with reference to the drawings. However, the present invention is not limited to the embodiments.

### Embodiment 1

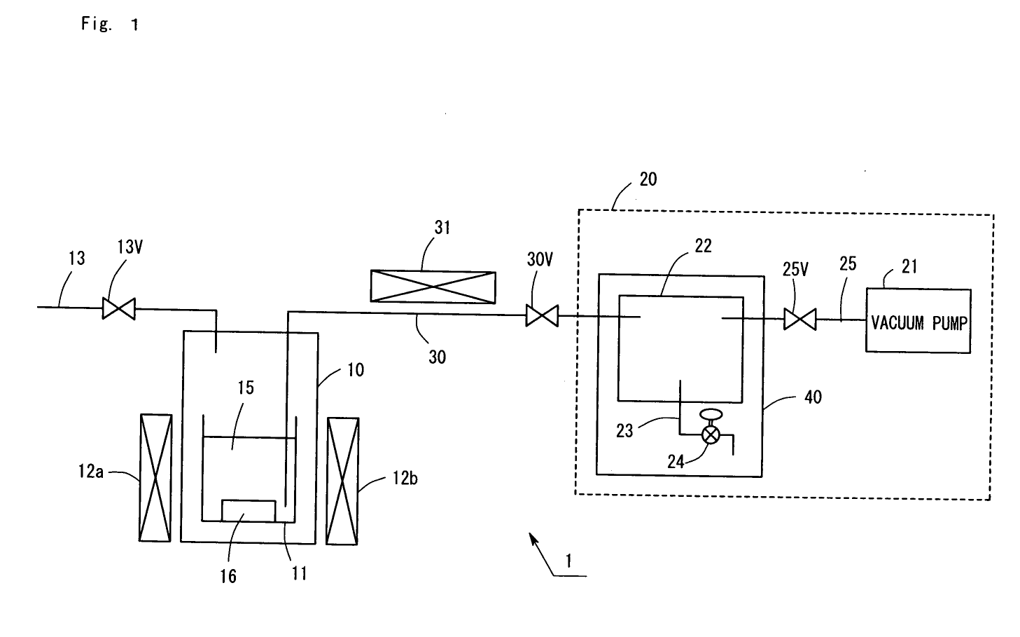

FIG. 1 schematically shows the configuration of a Group-III-nitride-semiconductor manufacturing apparatus 1 according to Embodiment 1 of the present invention. The configuration of the apparatus 1 is described below.

The Group-III-nitride-semiconductor manufacturing apparatus 1 includes a reaction vessel 10; a recovery device 20; discharge(suction) piping 30 connected to the recovery device 20 and extending into a crucible 11 disposed within the reaction vessel 10; first heating devices 12a and 12b for heating the reaction vessel 10; and a second heating device 31 for heating the discharge piping 30.

The crucible 11 is disposed within the reaction vessel 10 and contains a mixed melt 15 of Ga and Na, which serves as flux, as well as a seed crystal 16. The first heating devices 12a and 12b for heating the crucible 11 are disposed laterally externally of the reaction vessel 10. Supply piping 13 is connected to the reaction vessel 10, and nitrogen is supplied into the reaction vessel 10 through the supply piping 13. A valve 13v is provided in the supply piping 13. The valve 13v is used to adjust the supply of nitrogen into the reaction vessel 10 and to adjust the pressure in the reaction vessel 10.

The recover device 20 includes a vacuum pump 21; a holding vessel 22; piping 23 connected to the holding vessel 22; a faucet 24 attached to the piping 23; and piping 25, which connects the vacuum pump 21 and the holding vessel 22 to each other. A valve 25v is provided in the piping 25. The discharge piping 30 is connected to the holding vessel 22. The holding vessel 22, the piping 23, and the faucet 24 are disposed within a glove box 40. The interior of the holding vessel 22 is maintained at a temperature of about 100° C. in order to hold Na in a liquid state. Na contained in the holding vessel 22 can be freely drawn by opening and closing the faucet 24. The glove box 40 is filled with argon gas. Therefore, liquid Na can be poured into a container, such as a crucible, through the faucet 24 without involvement of oxidation of Na or a like problem.

The discharge piping 30 is connected to the holding vessel 22 and extends into the crucible 11 disposed within the reaction vessel 10. The second heating device 31 heats the discharge piping 30 so as to maintain the discharge piping 30 at a temperature of about 100° C. A valve 30v is provided in the discharge piping 30. After completion of a crystal-growing process, liquid Na is discharged or sucked and transferred into the holding vessel 22 through the discharge piping 30.

After completion of the crystal-growing process and in a state in which Na is held at 98° C. or higher, at which Na is not solidified, the recovery device 20 discharges or sucks liquid Na from the crucible 11 and holds the discharged or sucked liquid Na in the holding vessel 22 through the following operation.

First, the valve 30v is closed, and the valve 25v is held opened. The vacuum pump 21 is activated to evacuate the holding vessel 22 to a vacuum, and then the valve 25v is closed. Subsequently, the valve 30v is opened. By this procedure, due to a pressure difference, the liquid Na contained in the crucible 11 is discharged or sucked into the holding vessel 22 through the discharge piping 30.

Next will be described a method for manufacturing a Group III nitride semiconductor by use of the Group-III-nitride-semiconductor manufacturing apparatus 1 of Embodiment 1.

First, a mixed melt of Ga and Na, which serves as flux, and a seed crystal (a GaN substrate) are placed in the crucible 11. The crucible 11 is placed within the reaction vessel 10. The valve 13v is opened to supply nitrogen into the reaction vessel 10, and the crucible 11 is heated by means of the first heating devices 12a and 12b, so as to maintain the internal pressure of the reaction vessel 10 at about 5 MPa and to maintain the temperature of the crucible 11 at 800° C. for about 100 hours. By this procedure, a GaN crystal grows on the surface of the seed crystal.

After completion of the above-mentioned crystal-growing process, the temperature of the reaction vessel 10 is lowered. When the temperature of the crucible 11 is 100° C. or higher, liquid Na remaining in the crucible 11 is discharged and recovered by means of the recovery device 20. The recovery work is carried out at a crucible temperature of 100° C. or higher, since the melting point of Na is about 98° C. In order to facilitate the recovery work, liquid Na is desirably recovered when the temperature of the crucible 11 is within a range of 100° C. to 200° C. inclusive.

Impurities with high vapor pressure are vaporized in the course of crystal growth. Since such vaporized impurities are ejected together with the exhaust, Na remaining after completion of the crystal-growing process does not contain impurities with high vapor pressure, and is thus of high purity. Therefore, reuse, as flux, of Na recovered by the recovery device 20 enables manufacture of a Group III nitride semiconductor whose concentration of impurities is low.

### Embodiment 2

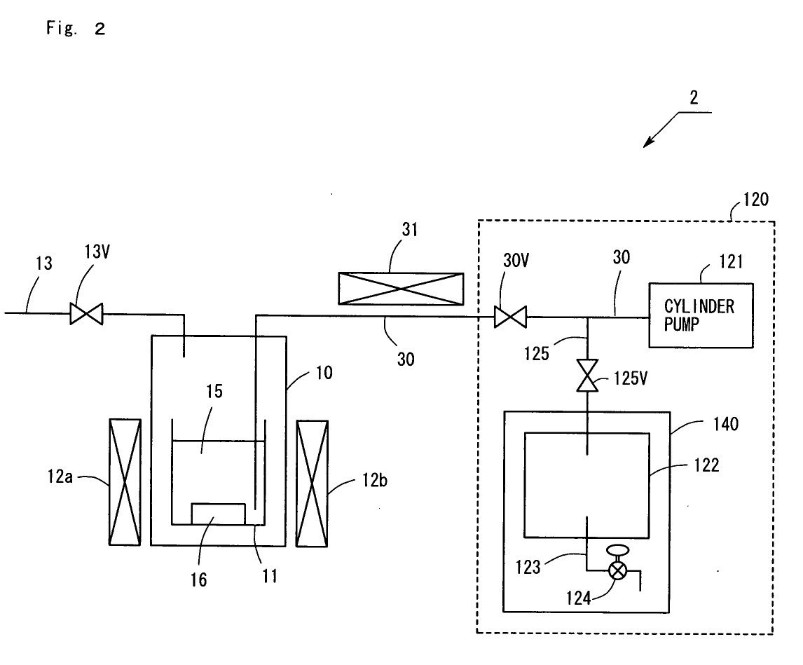

FIG. 2 schematically shows the configuration of a Group-III-nitride-semiconductor manufacturing apparatus 2 according to Embodiment 2 of the present invention. The Group-III-nitride-semiconductor manufacturing apparatus 2 is similar in configuration to the Group-III-nitride-semiconductor manufacturing apparatus 1, except that a recovery device 120 differs in configuration from the recovery device 20.

The recovery device 120 includes a cylinder pump 121 connected to the discharge piping 30; piping 125, which branches off from the discharge piping 30; a valve 125v provided in the piping 125; a holding vessel 122 connected to the piping 125; piping 123 connected to the holding vessel 122; and a faucet 124 attached to the piping 123. The holding vessel 122, the piping 123, and the faucet 124 are disposed within a glove box 140. As in the case of Embodiment 1, the interior of the holding vessel 122 is maintained at a temperature of about 100° C. Na contained in the holding vessel 122 can be freely drawn by opening and closing the faucet 124. The glove box 140 is filled with argon gas. Therefore, as in the case of Embodiment 1, liquid Na can be poured into a container, such as a crucible, without involvement of oxidation of Na or a like problem.

After completion of the crystal-growing process and in a state in which Na is held at 98° C. or higher, at which Na is not solidified, the recovery device 120 discharges liquid Na from the crucible 11 and holds the discharged liquid Na in the holding vessel 122 through the following operation.

First, the valve 30v is opened, and the valve 125v is held closed. In this condition, a piston of the cylinder pump 121 is pulled so as to reduce the pressure within the discharge piping 30, thereby discharging liquid Na from the crucible 11 into the discharge piping 30 and the cylinder pump 121. Next, the valve 30v is closed, and the valve 125v is opened. The piston of the cylinder pump 121 is pushed in, thereby introducing the liquid Na into the holding vessel 122 from the discharge piping 30 and the cylinder pump 121. In this manner, Na of high purity can be recovered and reused as flux.

### Embodiment 3

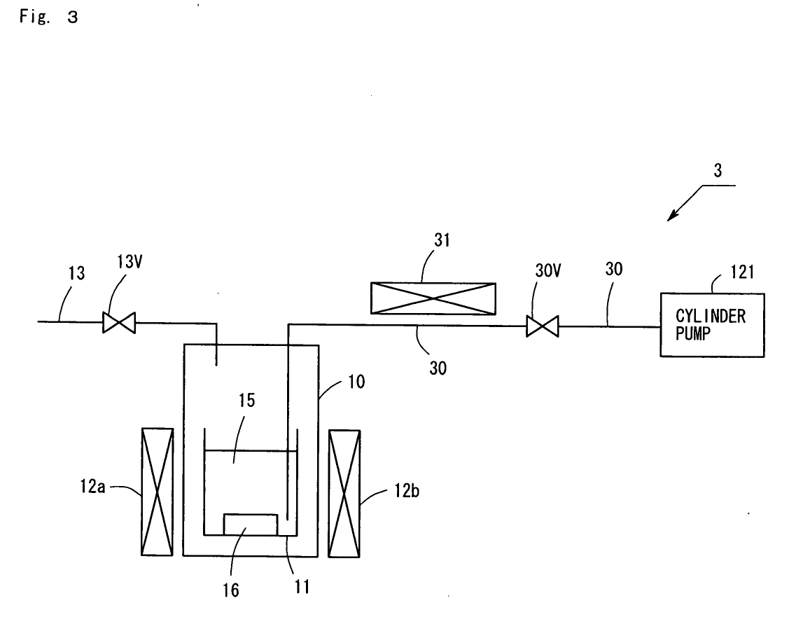

FIG. 3 schematically shows the configuration of a Group-III-nitride-semiconductor manufacturing apparatus 3 according to Embodiment 3 of the present invention. The Group-III-nitride-semiconductor manufacturing apparatus 3 is configured such that all components except the cylinder pump 121 are removed from the recovery device 120 in the Group-III-nitride-semiconductor manufacturing apparatus 2. That is, in the Group-III-nitride-semiconductor manufacturing apparatus 3, a recovery device is composed solely of the cylinder pump 121.

After completion of the crystal-growing process and in a state in which Na is held at 98° C. or higher, at which Na is not solidified, the cylinder pump 121, which serves as a recovery device, discharges liquid Na from the crucible 11 and holds the discharged liquid Na through the following operation. The valve 30v is opened, and a piston of the cylinder pump 121 is pulled, thereby discharging liquid Na from the crucible 11 into the discharge piping 30 and the cylinder pump 121. Next, the valve 30v is closed, thereby holding the discharged liquid Na in the discharge piping 30 and the cylinder pump 121. For reuse of Na, the valve 30v is opened, and the piston of the cylinder pump 121 is pushed in, thereby returning the liquid Na to the crucible 11 disposed in the reaction vessel 10.

The above-described Embodiments use the vacuum pump and the cylinder pump for discharging Na. However, any other type of pump can be used so long as the pump can establish reduced pressure.

The above-described Embodiments use Na as flux. However, potassium (K) or the like may be used as flux. Furthermore, lithium (Li), magnesium (Mg), or an alkaline-earth metal such as calcium (Ca) may be added to flux. Even in this case, flux can be discharged, held, and reused by operating the recovery device of the Group-III-nitride-semiconductor manufacturing apparatus at a temperature equal to or higher than the melting point of flux.

What is claimed is:

1. An apparatus for manufacturing a Group III nitride semiconductor, comprising:
a reaction vessel which holds, in a molten state, a Group III metal, and flux containing at least an alkali metal;
a first heating device for heating the reaction vessel;
a supply device for supplying a gas containing at least nitrogen into the reaction vessel;
discharge piping extending into the reaction vessel; and
a recovery device connected to the discharge piping and adapted to discharge, after completion of crystal growth, the flux liquefied in the reaction vessel.

2. An apparatus for manufacturing a Group III nitride semiconductor according to claim 1, further comprising a second heating device for heating the discharge piping.

3. An apparatus for manufacturing a Group III nitride semiconductor according to claim 1, wherein the flux contains sodium.

4. An apparatus for manufacturing a Group III nitride semiconductor according to claim 1, wherein the recovery device comprises a holding vessel for holding the flux in a liquid state.

5. An apparatus for manufacturing a Group III nitride semiconductor according to claim 2, wherein the recovery device comprises a holding vessel for holding the flux in a liquid state.

6. An apparatus for manufacturing a Group III nitride semiconductor according to claim 4, wherein
the holding vessel has a faucet through which the flux is drawn from the holding vessel, and
the faucet is disposed within a glove box filled with a gas which does not react with the flux.

7. An apparatus for manufacturing a Group III nitride semiconductor according to claim 5, wherein
the holding vessel has a faucet through which the flux is drawn from the holding vessel, and
the faucet is disposed within a glove box filled with a gas which does not react with the flux.

8. An apparatus for manufacturing a Group III nitride semiconductor according to claim 1, wherein the recovery device comprises a vacuum pump, and the flux is discharged by means of the vacuum pump.

9. An apparatus for manufacturing a Group III nitride semiconductor according to claim 2, wherein the recovery device comprises a vacuum pump, and the flux is discharged by means of the vacuum pump.

10. An apparatus for manufacturing a Group III nitride semiconductor according to claim 4, wherein the recovery device comprises a vacuum pump, and the flux is discharged by means of the vacuum pump.

11. An apparatus for manufacturing a Group III nitride semiconductor according to claim 6, wherein the recovery device comprises a vacuum pump, and the flux is discharged by means of the vacuum pump.

12. An apparatus for manufacturing a Group III nitride semiconductor according to claim 1, wherein the recovery device comprises a cylinder pump, and the flux is discharged by means of the cylinder pump.

13. An apparatus for manufacturing a Group III nitride semiconductor according to claim 2, wherein the recovery device comprises a cylinder pump, and the flux is discharged by means of the cylinder pump.

14. An apparatus for manufacturing a Group III nitride semiconductor according to claim 4, wherein the recovery device comprises a cylinder pump, and the flux is discharged by means of the cylinder pump.

15. An apparatus for manufacturing a Group III nitride semiconductor according to claim 6, wherein the recovery device comprises a cylinder pump, and the flux is discharged by means of the cylinder pump.

16. An apparatus for manufacturing a Group III nitride semiconductor according to claim 1, wherein the Group III metal is gallium.

17. A method for manufacturing a Group III nitride semiconductor according to a flux method, the method comprising:
growing a Group III nitride semiconductor crystal from a mixed melt of a Group III metal and flux containing at least an alkali metal, and a gas containing at least nitrogen; and
recovering and discharging the flux at a temperature higher than a melting point of the flux for recovery of the flux after completion of crystal growth.

18. A method for manufacturing a Group III nitride semiconductor according to claim 17, wherein the flux contains sodium.

19. A method for manufacturing a Group III nitride semiconductor according to claim 18, wherein the recovering is carried out when the temperature of the flux is within a range of 100° C. to 200° C. inclusive.
